(19) United States
(12) Patent Application Publication
(10) Pub. No.: US 2025/0180202 A1
(43) Pub. Date: Jun. 5, 2025

(54) CONSTANT-TEMPERATURE HEATING DEVICE AND FLUID HEATING ELECTRIC APPLIANCE WITH SAME

(71) Applicant: Millplan Electric Appliance (Shen Zhen) Co., Limited, Shenzhen (CN)

(72) Inventor: Ngan Chi CHAN, Shenzhen (CN)

(73) Assignee: Millplan Electric Appliance (Shen Zhen) Co., Limited, Shenzhen (CN)

(21) Appl. No.: 19/031,458

(22) Filed: Jan. 18, 2025

Related U.S. Application Data
(63) Continuation of application No. PCT/CN2024/092351, filed on May 10, 2024.

(30) Foreign Application Priority Data
Nov. 30, 2023 (CN) 202311627116.3
Nov. 30, 2023 (CN) 202323264020.3

(51) Int. Cl. F22B 35/08; D06F 87/00; H05K 7/20

(52) U.S. Cl. CPC F22B 35/08; H05K 7/20254; H05K 7/20272; D06F 87/00

(57) ABSTRACT

Disclosed are a constant temperature heating device and fluid heating electrical appliances with the same. The constant temperature heating device comprises a water pump, a heating boiler, a liquid delivery pipeline, and a control circuit. The water pump and the heating boiler are connected through the liquid delivery pipeline, respectively. The water pump is used for pumping liquid into the heating boiler under the control of the control circuit, so as to heat the liquid through the heating boiler. The control circuit comprises an electronic control switch and a controller. The electronic control switch is arranged on a power supply circuit of the heating boiler, and the controller is used for carrying out heating control of the liquid in the heating boiler through the electronic control switch.

### CROSS-REFERENCE TO RELATED APPLICATIONS

This application is a continuation of International Application No. PCT/CN2024/092351, filed on May 10, 2024, which claims priority to Chinese Patent Application No. 202311627116.3, filed on Nov. 30, 2023, and Chinese Patent Application No. 202323264020.3, filed on Nov. 30, 2023. All of the aforementioned applications are incorporated herein by reference in their entireties.

### TECHNICAL FIELD

The present application pertains to the technical field of fluid heating electric appliances, and particularly relates to a constant temperature heating device and a fluid heating electric appliance with the same.

### BACKGROUND

Liquid heating electric appliances such as garment steamers and evaporators usually heat liquid through a heater to reach a relatively high temperature range, thereby converting the liquid into gas, and further serving purposes, such as ironing clothes and performing hair steam care, by outputting steam at relatively high temperatures.

With reference to FIG. 1 and FIG. 2, in the prior art, the temperature detection and control of the garment steamer are mainly controlled through a constant temperature switch. The constant temperature switch is mounted on a power supply circuit of the heater and used for switch control of the power supply circuit of the heater. When the constant temperature switch detects that the temperature is higher than the upper limit temperature value of the constant temperature switch, the constant temperature switch will cut off the power supply circuit, and at this moment, the heater will stop heating. Due to heat dissipation to the outside, the liquid in the boiler of the garment steamer will cool down. When the temperature drops below the lower limit temperature value of the constant temperature switch, the constant temperature switch will be switched on again, so that the heater has the power supply circuit switched on again and continues to heat the liquid in the boiler of the garment steamer. In this way, it is ensured that the temperature of the liquid stays within a certain temperature range. As shown in FIG. 7, the temperature of the liquid or vapor fluctuates around plus or minus 25° C., which is due to mechanical characteristics of switch-on and switch-off of the constant temperature switch. The switch-on and switch-off of the constant temperature switch directly require a relatively large temperature difference. In other words, as the constant temperature switch is a mechanical sensing switch with relatively slow response, the liquid in the boiler of the garment steamer has relatively large temperature fluctuations, making it difficult to meet the high-precision constant temperature heating requirement.

### SUMMARY

The present application aims to, at least to a certain extent, solve one of the technical problems in relevant techniques. As such, it is one objective of the present application to propose a constant temperature heating device and a fluid heating electric appliance with the same.

On the one hand, to achieve the above objective, according to embodiments of the present application, a constant temperature heating device comprises: a water pump, a heating boiler, a liquid delivery pipeline, and a control circuit, wherein the water pump and the heating boiler are connected through the liquid delivery pipeline, respectively; the water pump is used for pumping liquid into the heating boiler under the control of the control circuit, so as to heat the liquid through the heating boiler;

the control circuit comprises an electronic control switch and a controller; the electronic control switch is arranged on a power supply circuit of the heating boiler, and the controller is used for carrying out heating control of the liquid in the heating boiler through the electronic control switch.

Further, according to one embodiment of the present application, the constant temperature heating device further comprises a temperature sensor, which is used for detecting the temperature of the heating boiler, wherein the controller is further used for obtaining a temperature value of the heating boiler through the temperature sensor, and carrying out constant temperature heating control of the heating boiler through the electronic control switch according to the temperature value.

Further, according to one embodiment of the present application, the electronic control switch comprises:
a first silicon-controlled rectifier, which is arranged on the power supply circuit of the heating boiler, and has a control gate for receiving a control signal from the controller to perform switch control on the power supply circuit of the heating boiler.

Further, according to one embodiment of the present application, the first silicon-controlled rectifier has a heat-dispersing surface that is connected to the liquid delivery pipeline, so as to dissipate heat from the silicon-controlled rectifier through the liquid delivery pipeline.

Further, according to one embodiment of the present application, the constant temperature heating device further comprises:
a heat-dispersing water tank, through which the heat-dispersing surface of the first silicon-controlled rectifier is connected to the liquid delivery pipeline; wherein, a water inlet and a water outlet are arranged on the heat-dispersing water tank, the water inlet is connected to the water pump through a water pipe, and the water outlet is connected to the heating device through a water pipe; alternatively, the water inlet is connected to a water storage tank through a water pipe, and the water outlet is connected to the water pump.

Further, according to one embodiment of the present application, the constant temperature heating device further comprises: a heat sink, which has one side that fits to the heat-dispersing surface of the first silicon-controlled rectifier and the other side that fits to the heat-dispersing water tank, so as to guide the heat of the first silicon-controlled rectifier to the heat-dispersing water tank.

Further, according to one embodiment of the present application, the first silicon-controlled rectifier has a first anode that is connected to a first power supply terminal of a power source and a second anode that is connected to a first power supply terminal of the heating boiler, the heating boiler has a second power supply terminal that is connected to a second power supply terminal of the power source, and the control gate of the first silicon-controlled rectifier is used for controlling switch-on and switch-off of the first anode and the second anode under the action of the control signal of the controller.

Further, according to one embodiment of the present application, the electronic control switch further comprises:
a first silicon-controlled rectifier drive circuit, through which the controller is connected to the control gate of the first silicon-controlled rectifier to drive the switch-on and switch-off of the first anode and the second anode of the first silicon-controlled rectifier.

Further, according to one embodiment of the present application, the first silicon-controlled rectifier drive circuit comprises:
a triode Q4, which has a base that is connected to a control terminal of the controller through a resistor R17, an emitter that is connected to a reference ground, and a collector that is connected to the control gate of the first silicon-controlled rectifier.

On the other hand, the embodiments of the present application further provide a fluid heating electric appliance, comprising:
a housing;
the constant temperature heating device, which is mounted in the housing.

In the constant temperature heating device provided in the embodiments of the present application, the water pump and the heating boiler are connected through the liquid delivery pipeline, respectively; the water pump is used for pumping liquid into the heating boiler under the control of the control circuit, so as to heat the liquid through the heating boiler; the control circuit comprises an electronic control switch and a controller; the electronic control switch is arranged on a power supply circuit of the heating boiler, and the controller is used for carrying out heating control of the liquid in the heating boiler through the electronic control switch. Since the electronic control switch can be switched on or off quickly under the control of the controller, the high-precision heating control of a heater can be realized, which can greatly reduce the relatively large temperature fluctuations of the liquid in the boiler of the garment steamer as caused by the relatively slow switch response, and meet the high-precision constant temperature heating requirement in a better manner.

### BRIEF DESCRIPTION OF THE DRAWINGS

FIG. 1 is a structure diagram of a circuit for controlling constant temperature heating of a load through a constant temperature control switch in the prior art.

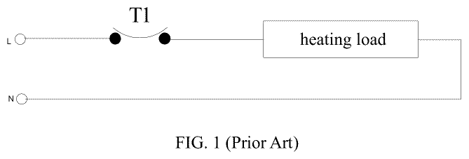

FIG. 2 is a structure diagram of a constant temperature heating device in the prior art.

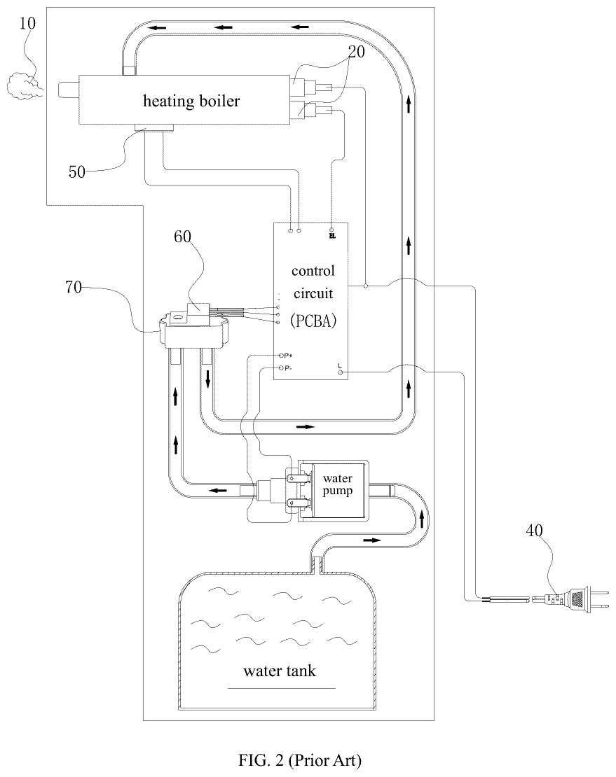

FIG. 3 is a structure diagram of a constant temperature heating device provided in an embodiment of the present application.

FIG. 4 is a circuit diagram of a control circuit connected with a temperature sensor, a heater, and a water pump provided in an embodiment of the present application.

FIG. 5 is a structure diagram of a garment steamer with a constant temperature heating device provided in an embodiment of the present application.

FIG. 6 is a structure diagram of an evaporator with a constant temperature heating device provided in an embodiment of the present application.

FIG. 7 is a temperature waveform diagram under constant temperature heating control of a constant temperature switch in the prior art.

FIG. 8 is a temperature waveform diagram under constant temperature heating control of a constant temperature heating device provided in an embodiment of the present application.

### DETAILED DESCRIPTION OF THE EMBODIMENTS

To facilitate persons skilled in the art understanding the solutions of the present application, the technical solutions in the embodiments of the present application the following will be described below in combination with the drawings in a clear and complete manner. Unless otherwise defined, all technical and scientific terms used in this text have the same meanings as those commonly understood by persons skilled in the art to which the present application belongs. The terms used in the description of the present application are only for the purpose of describing specific embodiments, and are not intended to limit the present application.

The reference to “embodiment” in this text means that specific features, structures, or characteristics described in combination with the embodiment can be included in at least one embodiment of the present application. The word that appears in various positions in the description does not necessarily refer to the same embodiment, nor is it an independent or alternative embodiment that is mutually exclusive with other embodiments. Persons skilled in the art explicitly and implicitly understand that the embodiment described in this text can be combined with other embodiments.

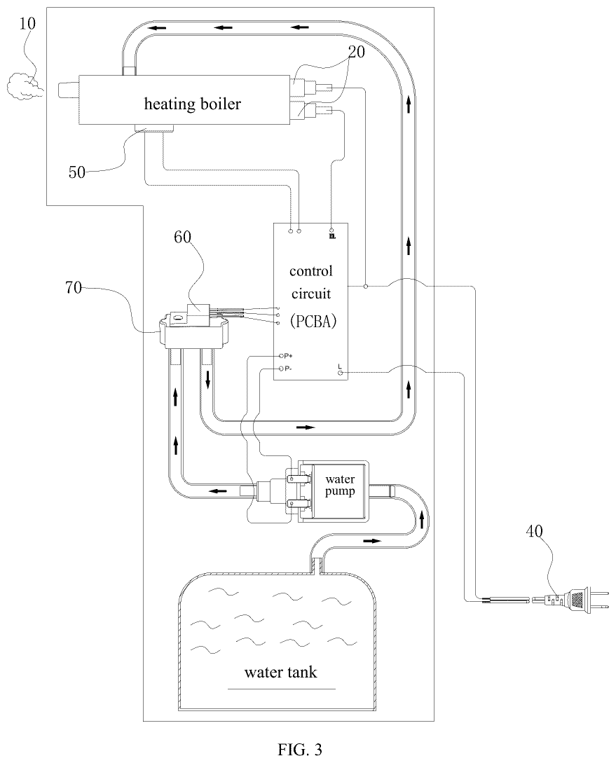

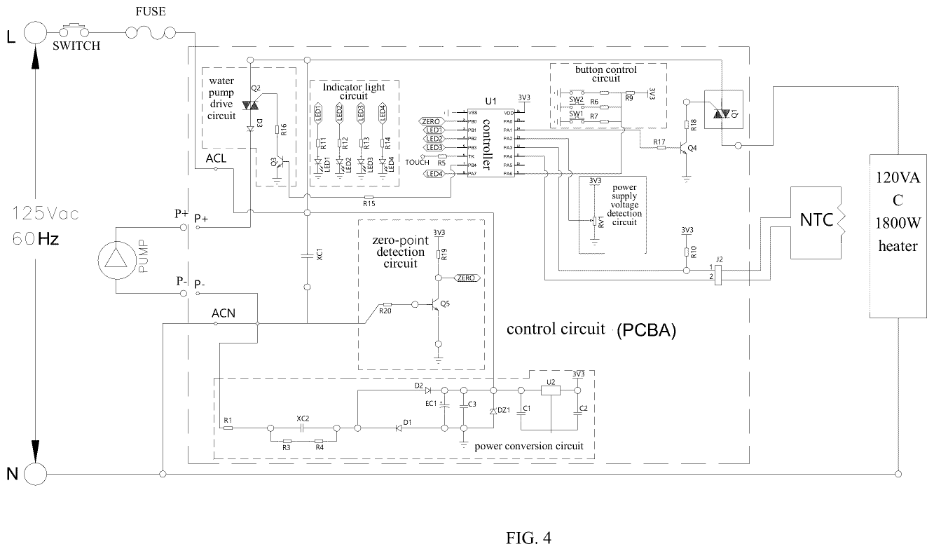

On the one hand, with reference to FIGS. 3 and 4, the embodiments of the present application provide a constant temperature heating device, comprising: a water pump, a heating boiler, a liquid delivery pipeline, and a control circuit, wherein the water pump and the heating boiler are connected through the liquid delivery pipeline, respectively; the water pump is used for pumping liquid into the heating boiler under the control of the control circuit, so as to heat the liquid through the heating boiler; the control circuit comprises an electronic control switch and a controller; the electronic control switch is arranged on a power supply circuit of the heating boiler, and the controller is used for carrying out heating control of the liquid in the heating boiler through the electronic control switch.

As shown in FIGS. 3 and 4, in the embodiments of the present application, by replacing the existing constant temperature switch with the electronic control switch, the power supply circuit of a heater 20 in the heating boiler is under switch control, so as to realize heating control of the liquid in the heating boiler. The electronic control switch has a control terminal that is connected to a control signal output terminal of the controller. When the controller outputs a switch-on signal, it can control the electronic control switch to be switched on quickly; on the contrary, when the controller outputs a switch-off signal to the control terminal of the electronic control switch, it can control the electronic control switch to be switched off quickly. Since the electronic control switch can be quickly switched on or off under the control of the controller, the high-precision heating control of the heater 20 can be realized, which can greatly reduce the relatively large temperature fluctuations of the liquid in the boiler of a garment steamer as caused by the relatively slow switch response, and meet the high-precision constant temperature heating requirement in a better manner.

More specifically, as shown in FIG. 3, the water pump and the heating boiler are connected through the liquid delivery pipeline; the constant temperature heating device can further comprise a water tank; the water tank can hold liquid; the liquid can be liquid water. The water pump and the water tank can be connected through the liquid delivery pipeline. In this way, under the control of the controller, the water pump can pump an appropriate amount of liquid into the heating boiler for heating. Since the electronic control switch can be switched on or off quickly under the control of the controller, the high-precision control of the switch-on or switch-off time of the power supply to the heater 20 can be realized, which enables the high-precision heating control of the temperature of the liquid in the heating boiler.

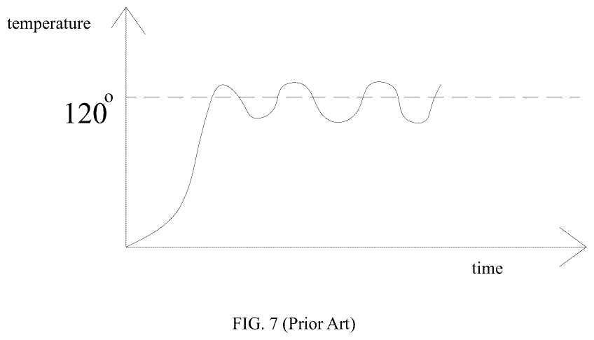

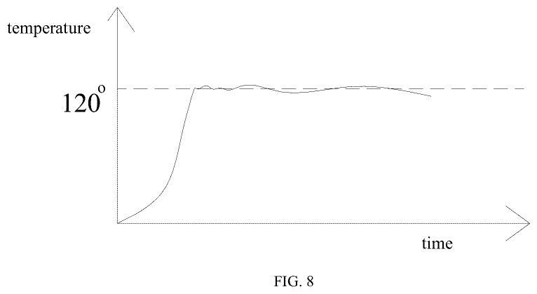

With reference to FIGS. 3 and 4, the constant temperature heating device further comprises a temperature sensor 50 for detecting the temperature of the heating boiler; the controller is further used for obtaining a temperature value of the heating boiler through the temperature sensor 50, and carrying out constant temperature heating control of the heating boiler through the electronic control switch according to the temperature value. As shown in FIG. 3, the temperature sensor 50 can be arranged on the heating boiler; in this way, the temperature of the heating boiler can be detected to obtain the temperature of the liquid in the heating boiler. Moreover, the detected temperature is output to the controller, and the controller can control the electronic control switch to be switched on or off according to the detected temperature, thereby realizing heating control of the liquid in the heating boiler. In the constant temperature heating control, when the controller detects a temperature lower than the set value (such as 120° C.) through the temperature sensor 50, it can output a switch-on control signal to control the electronic control switch to be switched on, so as to switch on the power supply circuit of the heater 20, which can heat the liquid in the heating boiler. When the controller detects that the temperature of the liquid in the heating boiler is higher than the set value through the temperature sensor 50, it can output a switch-off control signal to control the electronic control switch to be switched off, so that the power supply circuit of the heater 20 is switched off and the heater 20 stops heating the liquid in the heating boiler. In this way, it can be ensured that the temperature of the liquid in the heating boiler maintains in a constant temperature state. Since the temperature sensor 50 can perform real-time detection on the temperature of the liquid in the heating boiler and perform rapid heating control on the electronic control switch through the controller, it can be ensured that the temperature in the heating boiler is in a constant temperature state, and the fluctuation amplitude of the temperature is relatively small. As shown in FIG. 8, it is found in the actual measurement that in the manner of detecting the temperature of the heating boiler through the temperature sensor 50 and controlling switch-on and switch-off of the electronic control switch through the controller, the temperature of the liquid in the heating boiler can be kept in a constant temperature state; compared with the control manner of the constant temperature switch in the prior art, the fluctuation amplitude of the temperature is relatively small (the temperature waveform of heating through the constant temperature switch is shown in FIG. 7). Therefore, the high-precision liquid constant temperature control requirement can be met.

As shown in FIG. 4, the temperature sensor 50 can be a thermistor NTC, which has one end that is connected to one end of the controller U1 and the other end that is connected to one end of the resistor R10; the other end of the resistor R10 is connected to a pull-up power source 3V3; the thermistor NTC1 and the resistor R10 have a common terminal that is connected to a temperature detection terminal of the controller. The working process of the temperature detection circuit is as follows: the thermistor NTC and the resistor R10 are connected in series to form a voltage divider circuit, so that 3.3V voltage is subjected to voltage division and then output to the controller U1 through a NTC signal. Due to the linear relationship between the resistance value of the thermistor NTC and the temperature, the controller obtains a corresponding temperature value by reading divided voltage values of the thermistor NTC and the resistor R10, and controls switch-on or switch-off of the first silicon-controlled rectifier Q1 according to the temperature value.

With reference to FIGS. 3 and 4, the electronic control switch comprises a first silicon-controlled rectifier 60 (Q1), which is arranged on the power supply circuit of the heating boiler, and has a control gate for receiving a control signal from the controller to perform switch control on the power supply circuit of the heating boiler. As shown in FIGS. 3 and 4, a silicon-controlled rectifier can serve as the electronic control switch to perform switch-on or switch-off control on the power supply circuit of the heater 20. Featured with the high switch-on and switch-off response speed and long service life, the silicon-controlled rectifier can meet the constant temperature control requirement of the liquid. Wherein, the first silicon-controlled rectifier 60 (Q1) have two anodes that are connected in series on the power supply circuit of the heater 20, and a control gate that is connected to the control terminal. As shown in FIG. 4, the first silicon-controlled rectifier 60 (Q1) has a first anode that is connected to a first power supply terminal of a power source and a second anode that is connected to a first power supply terminal of the heating boiler; the heating boiler has a second power supply terminal that is connected to a second power supply terminal of the power source; the control gate of the first silicon-controlled rectifier 60 (Q1) is used for controlling switch-on and switch-off of the first anode and the second anode under the action of the control signal of the controller. Wherein, during the switch-on between the two anodes of the first silicon-controlled rectifier 60 (Q1), the power source supplies power to the heater 20 through the first silicon-controlled rectifier 60 (Q1). Due to the switch-on of the power source at both ends of the heater 20, the heater 20 can heat the liquid in the heating boiler. On the contrary, during the switch-off between the two anodes of the first silicon-controlled rectifier 60 (Q1), the heater 20 stops heating the liquid in the heating boiler due to the switch-off of the power supply circuit.

With reference to FIG. 4, the electronic control switch further comprises a first silicon-controlled rectifier 60 drive circuit, through which the controller is connected to the control gate of the first silicon-controlled rectifier 60, so as to drive the switch-on or switch-off of the first anode and the second anode of the first silicon-controlled rectifier 60. The first silicon-controlled rectifier 60 (Q1) can be under drive control through the first silicon-controlled rectifier 60 drive circuit. In this way, the first silicon-controlled rectifier 60 (Q1) can be switched on or off quickly under the action of the first silicon-controlled rectifier 60 drive circuit, which solves the problem that the controller is weak in output signal and poor in drive capability. As shown in FIG. 4, the first silicon-controlled rectifier 60 drive circuit comprises: a triode Q4, which has a base that is connected to a control terminal of the controller through a resistor R17, an emitter that is connected to a reference, and a collector that is connected to the control gate of the first silicon-controlled rectifier 60.

Specifically, the working process of the first silicon-controlled rectifier 60 drive circuit is as follows: when the controller outputs a high-level signal through a pin 14, the high-level signal can generate on-current between the base and emitter of the triode Q4, and the on-current enables the switch-on between the collector and the emitter of transistor Q4; as such, the control gate of the first silicon-controlled rectifier 60 (Q1) can be pulled down to the level voltage of the reference ground; under the action of the power source, the first silicon-controlled rectifier 60 (Q1) can be switched on; the power source is output to the heater 20 and put through at both ends of the heater 20, and the heater 20 starts heating; on the contrary, when the controller outputs a low-level signal through the pin 14, the triode Q4 is switched off; in this way, the control gate of the first silicon-controlled rectifier 60 (Q1) is free of a switch-on triggering signal, the first silicon-controlled rectifier 60 (Q1) is switched off, the power source is cut off at both ends of the heater 20, and the heater 20 stops heating.

With reference to FIG. 3, the first silicon-controlled rectifier has a heat-dispersing surface that is connected to the liquid delivery pipeline, so as to dissipate heat from the first silicon-controlled rectifier through the liquid delivery pipeline. As shown in FIG. 3, by introducing a silicon-controlled rectifier in place of a constant temperature switch in the mechanical structure, the switch-on speed of the power supply circuit can be greatly increased to meet the high-precision heating temperature control requirement. However, as the heater 20 of fluid heating electric appliances such as garment steamers usually have a relatively high heating power (such as 1850 W), generally with a working current of around 10 A in a 220 V or 120 V AC power source, the silicon-controlled rectifier connected in series to the circuit of the power source generates severe heat. Due to the small space of household fluid constant temperature heating equipment, the heat generated by the silicon-controlled rectifier cannot be quickly dissipated through a heat sink, resulting in a rapid increase in the heat during the operation of the silicon-controlled rectifier. When the heat generated by the silicon-controlled rectifier is increased up to the maximum tolerable temperature, the silicon-controlled rectifier may fail to function properly; during control, the silicon-controlled rectifier malfunctions; in severe cases, the silicon-controlled rectifier may even catch fire. Therefore, rapid heat dissipation for the silicon-controlled rectifier in the small space is taken into consideration. Since the liquid in the water tank of the constant temperature heating device is usually at room temperature, the liquid at room temperature on the liquid delivery pipeline can be used to dissipate heat from the first silicon-controlled rectifier 60. The heat-dispersing surface of the first silicon-controlled rectifier 60 can bring the heat out of the first silicon-controlled rectifier 60 and transfer it to the liquid in the liquid delivery pipeline. As the liquid in the liquid delivery pipeline takes away the heat emitted by the first silicon-controlled rectifier 60, the purpose of cooling the first silicon-controlled rectifier 60 rapidly is achieved, and the overheating problem during operation of the first silicon-controlled rectifier 60 is avoided. In addition, the heat generated by the first silicon-controlled rectifier 60 can also act on the liquid to a certain extent, and raise the temperature of the liquid to a certain extent, which makes more reasonable and more sufficient use of electrical energy.

With reference to FIG. 3, the constant temperature heating device further comprises a heat-dispersing water tank 70, through which the heat-dispersing surface of the first silicon-controlled rectifier is connected to the liquid delivery pipeline; wherein, a water inlet and a water outlet are arranged on the heat-dispersing water tank 70, the water inlet is connected to the water pump through a water pipe, and the water outlet is connected to the heating device through a water pipe; alternatively, the water inlet is connected to a water storage tank through a water pipe, and the water outlet is connected to the water pump. As shown in FIG. 3, to take away the heat generated by the first silicon-controlled rectifier in a better manner, one heat-dispersing water tank 70 can be added on the liquid delivery pipeline, and the water inlet and the water outlet of the heat-dispersing water tank 70 are connected to the liquid delivery pipeline, respectively. In this way, the liquid in the liquid delivery pipeline can enter the heat-dispersing water tank 70 through the water inlet and exit through the water outlet, thereby taking away the heat generated by the first silicon-controlled rectifier 60. As one end surface of the heat-dispersing water tank 70 fits to the heat-dispersing surface of the first silicon-controlled rectifier 60, the contact area between the first silicon-controlled rectifier 60 and the heat-dispersing water tank 70 is greatly increased, so that the heat generated by the first silicon-controlled rectifier 60 can be transferred to the liquid in the heat-dispersing water tank 70 through the heat-dispersing water tank 70 in a favorable manner; further, the heat generated by the first silicon-controlled rectifier 60 can be taken away quickly.

With reference to FIG. 3, the constant temperature heating device further comprises a heat sink, which has one side that fits to the heat-dispersing surface of the first silicon-controlled rectifier 60 and the other side that fits to the heat-dispersing water tank 70, so as to guide the heat of the first silicon-controlled rectifier 60 to the heat-dispersing water tank 70. In other words, one heat sink can be added between the heat-dispersing surface of the first silicon-controlled rectifier 60 and the water tank, and the heat sink can be an aluminum sheet. On the one hand, heat dissipation can be realized to a certain extent through the aluminum sheet. On the other hand, the aluminum sheet can quickly bring heat out of the first silicon-controlled rectifier 60 and increase the contact area between the aluminum sheet and the heat-dispersing water tank 70, so as to transfer the heat generated by the first silicon-controlled rectifier 60 to the liquid in the water tank in a better manner, thereby achieving a better heat dissipation effect.

With reference to FIG. 4, the control circuit further comprises a water pump drive circuit, which is respectively connected to the controller and the water pump to perform pumping drive control on the water pump under the control of the controller; the water pump drive circuit is arranged on the power supply circuit of the water pump. In this way, the power supply circuit of the water pump can be switched on or off under the control of the controller. When the power supply circuit of the water pump is switched on, the water pump starts working and pumps the liquid into the heating boiler for heating. When the power supply circuit of the water pump is switched off, the water pump stops pumping.

As shown in FIG. 4, the water pump drive circuit comprises a second silicon-controlled rectifier Q2, a diode D3, and a triode Q3; the second silicon-controlled rectifier Q2 has a first anode that is connected to one end of the power source and a second anode that is connected to an anode of the diode D3; the second diode D3 has a cathode that is connected to a positive terminal of the water pump; the water pump has a negative terminal that is connected to the other end of the power source; the triode Q3 has a collector that is connected to the control gate of the second silicon-controlled rectifier Q2 through a resistor R16, an emitter that is connected to the reference ground, and a base that is connected to a control terminal of the controller through a resistor R15.

The working process of the water pump drive circuit is as follows: when the controller outputs a high-level signal through a pin 7, the high-level signal can generate on-current between the base and the emitter of the triode Q3, and the on-current enables the switch-on between the collector and the emitter of transistor Q3; as such, the control gate of the second silicon-controlled rectifier Q2 can be pulled down to the level voltage of the reference ground; under the action of the power source, the second silicon-controlled rectifier Q2 can be switched on; the power source is output to the water pump and put through at both ends of the water pump, and the water pump starts pumping; on the contrary, when the controller outputs a low-level signal through the pin 7, the triode Q3 is switched off; in this way, the control gate of the second silicon-controlled rectifier Q2 is free of a switch-on triggering signal, the second silicon-controlled rectifier Q2 is switched off, the power source is cut off at both ends of the water pump, and the water pump stops pumping.

With reference to FIG. 4, the control circuit can further comprise a zero-point detection circuit, which is connected to the controller and the input AC, respectively; the controller obtains a zero-crossing signal of the input AC through the zero-crossing detection circuit; through the zero-crossing detection circuit, the zero-crossing signal of the input AC (power source) can be obtained, and the first silicon-controlled rectifier 60 and/or the second silicon-controlled rectifier can be controlled to be switched on when the zero-crossing signal arrives. In this way, it is achievable to avoid beginning to heat when the real-time voltage of the input AC is at a peak value, thereby avoiding the problems such as overload protection of the power source and/or suppression of generation of electric arc.

As shown in FIG. 4, the zero-point detection circuit comprises a triode Q5, which has a base that is connected to one end of an AC power source through a resistor, an emitter that is connected to the reference ground, and a collector that is connected to a 3.3V pull-up DC power source through a resistor R19, and further connected to a control terminal of the controller. As shown in FIG. 4, when the input AC is in the positive half wave, the triode Q5 can be switched on, and the collector of the triode Q5 outputs a low-level signal; when the input AC is in the negative half wave, the triode Q5 can be switched off, and the collector of the triode Q5 outputs a high-level signal. As the controller reads the ZERO signal terminal of the collector of the triode Q5, the zero-crossing signal of the input AC can be obtained.

With reference to FIG. 4, the control circuit can further comprise a button control circuit, which is connected to the controller; the button control circuit is provided with one or more buttons to send a control signal to the controller; as shown in FIG. 4, the button control circuit comprises a first control button SW1, a second control button SW2, and a third control button SW3; the first control button SW1 has one end that is connected to the reference ground and the other end that is connected to one end of a resistor R7; the other end of the resistor R7 is connected to a button signal detection terminal of the controller, and further connected to a 3.3V pull-up DC power source; the second control button SW2 has one end that is connected to the reference ground and the other end that is connected to the button signal detection terminal of the controller through a resistor R6; the third control button SW3 has one end that is connected to the reference ground and the other end that is connected to the button signal detection terminal of the controller through a resistor R8.

As shown in FIG. 4, the working process of the button control circuit is as follows: the two ends of the control buttons can be switched on by pressing the first control button SW1, the second control button SW2, and the third control button SW3; the resistors R6, R7, R8, and R9 form a voltage divider circuit; since the resistors R6, R7, and R8 have different resistance values, the first control button SW1, the second control button SW2, and the third control button SW3 can generate different voltage values when they are switched on; by reading the different voltage values, the controller can obtain different control signals and perform corresponding operations, such as stopping heating and stopping pumping.

With reference to FIG. 4, the control circuit can further comprise a power conversion circuit, which is connected to the input AC power and the controller, so as to convert the input AC into low-voltage DC before supplying power to the controller; since the input power source has mains AC with relatively high voltage such as 220V and 120V, it is necessary to convert the mains AC into relatively low voltage DC before flowing through the controller.

As shown in FIG. 4, the power conversion circuit comprises a diode D1, a diode D2, a capacitor CE1, a capacitor C3, a voltage regulator diode DZ1, and a DC voltage converter U2; the diode D1 has a cathode that is connected to one end of the AC power source through a capacitor XC2 and a resistor R1, and an anode that is connected to the reference ground; the diode D2 has an anode that is connected to the cathode of the diode D1, and a cathode that is connected to one end of the capacitor CE1; the other end of the capacitor CE1 is connected to the reference ground; the cathode of the diode D2 is further connected to one end of the capacitor C3; the other end of the capacitor C3 is connected to the reference ground; the cathode of the diode D2 is further connected to a cathode of the voltage regulator diode DZ1; an anode of the voltage regulator diode DZ1 is connected to the reference ground; the cathode of the diode D2 is further connected to an output terminal of the DC voltage converter U2; the output terminal of the DC voltage converter U2 outputs 3.3V low-voltage DC 3V3, which can supply power to the controller.

As shown in FIG. 4, in the power conversion circuit, the input mains AC can be rectified and output to both ends of the capacitors EC1 and C3 through the diodes D1 and D2, and after filtering through the capacitors EC1 and C3, output to both ends of the voltage regulator diode DZ1; after further voltage regulation through the voltage regulator diode DZ1, stable DC is output to the DC voltage converter U2, and converted into the voltage of the controller through the DC voltage converter U2, and the voltage is output. Wherein, the output low-voltage DC can be 3.3V low-voltage DC.

With reference to FIG. 4, the control circuit can further comprise an indicator light circuit, which is connected to the controller, and turn on or off the indicator light under the control of the controller to indicate the working status. As shown in FIG. 4, the indicator light circuit comprises a first LED light LED1, a second LED light LED2, a third LED light LED3, and a fourth LED light LED4, which have cathodes that are respectively connected to the reference ground, and anodes that are respectively connected to the control terminal of the controller through resistors. As shown in FIG. 4, the controller U1 can output a high-level signal through a pin 3, 4, 5, or 8 to turn on the first LED LED1, the second LED LED2, the third LED LED3, or the fourth LED LED4. On the contrary, when a low-level signal is output, the corresponding LED light can be turned off. As such, the working status can be indicated by turning on or off the corresponding LED light.

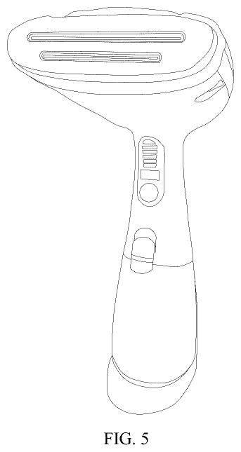

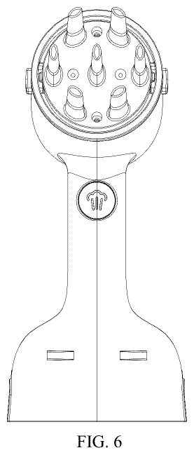

On the other hand, with reference to FIGS. 5 and 6, the embodiments of the present application further provide a fluid heating electric appliance, comprising a housing and the constant temperature heating device, which is mounted in the housing. Wherein, the fluid heating electric appliance can include evaporators, garment steamers, etc.

Among the elaborations in this description, those with reference to the terms such as “one embodiment”, “some embodiments”, “example”, “specific example”, and “some examples” mean that the specific features, structures, materials, or characteristics described in combination with the embodiment or example are included in at least one embodiment or example of the present application. In this description, the illustrative expressions of the above terms are not necessarily directed to the same embodiment or example. Moreover, the specific features, structures, materials, or characteristics as described can be combined in any one or more embodiments or examples in an appropriate manner.

The above content only relates to preferred embodiments of the present application, and does not limit the patent scope of the present application. Any equivalent structural transformation that is made by using the content of the description of the present application and the drawings under the application concept of the present application or direct/indirect application in other relevant technical fields falls within the scope of patent protection of the present application.

What is claimed is:

1. A constant temperature heating device, comprising: a water pump, a heating boiler, a liquid delivery pipeline, and a control circuit, wherein
the water pump and the heating boiler are connected through the liquid delivery pipeline, respectively; the water pump is used for pumping liquid into the heating boiler under the control of the control circuit, so as to heat the liquid through the heating boiler; and
the control circuit comprises an electronic control switch and a controller; the electronic control switch is arranged on a power supply circuit of the heating boiler, and the controller is used for carrying out heating control of the liquid in the heating boiler through the electronic control switch.

2. The constant temperature heating device according to claim 1, further comprising: a temperature sensor, which is used for detecting the temperature of the heating boiler, wherein the controller is further used for obtaining a temperature value of the heating boiler through the temperature sensor, and carrying out constant temperature heating control of the heating boiler through the electronic control switch according to the temperature value.

3. The constant temperature heating device according to claim 1, wherein the electronic control switch comprises:
a first silicon-controlled rectifier, which is arranged on the power supply circuit of the heating boiler, and has a control gate for receiving a control signal from the controller to perform switch control on the power supply circuit of the heating boiler.

4. The constant temperature heating device according to claim 3, wherein the first silicon-controlled rectifier has a heat-dispersing surface that is connected to the liquid delivery pipeline, so as to dissipate heat from the silicon-controlled rectifier through the liquid delivery pipeline.

5. The constant temperature heating device according to claim 4, further comprising:
a heat-dispersing water tank, through which the heat-dispersing surface of the first silicon-controlled rectifier is connected to the liquid delivery pipeline; wherein, a water inlet and a water outlet are arranged on the heat-dispersing water tank, the water inlet is connected to the water pump through a water pipe, and the water outlet is connected to the heating device through a water pipe; alternatively, the water inlet is connected to a water storage tank through a water pipe, and the water outlet is connected to the water pump.

6. The constant temperature heating device according to claim 5, further comprising: a heat sink, which has one side that fits to the heat-dispersing surface of the first silicon-controlled rectifier and the other side that fits to the heat-dispersing water tank, so as to guide the heat of the first silicon-controlled rectifier to the heat-dispersing water tank.

7. The constant temperature heating device according to claim 3, wherein the first silicon-controlled rectifier has a first anode that is connected to a first power supply terminal of a power source and a second anode that is connected to a first power supply terminal of the heating boiler, the heating boiler has a second power supply terminal that is connected to a second power supply terminal of the power source, and the control gate of the first silicon-controlled rectifier is used for controlling switch-on and switch-off of the first anode and the second anode under the action of the control signal of the controller.

8. The constant temperature heating device according to claim 7, wherein the electronic control switch further comprises:
a first silicon-controlled rectifier drive circuit, through which the controller is connected to the control gate of the first silicon-controlled rectifier to drive the switch-on and switch-off of the first anode and the second anode of the first silicon-controlled rectifier.

9. The constant temperature heating device according to claim 8, wherein the first silicon-controlled rectifier drive circuit comprises:
a triode Q4, which has a base that is connected to a control terminal of the controller through a resistor R17, an emitter that is connected to a reference ground, and a collector that is connected to the control gate of the first silicon-controlled rectifier.

10. A fluid heating electric appliance, comprising:
a housing;
the constant temperature heating device according to claim 1, which is mounted in the housing.
